(19) United States
(12) Patent Application Publication
(10) Pub. No.: US 2025/0291002 A1
(43) Pub. Date: Sep. 18, 2025

(54) ABNORMALITY DETECTION SYSTEM

(71) Applicant: TOYOTA JIDOSHA KABUSHIKI KAISHA, Toyota-shi (JP)

(72) Inventors: Yasuhiro KURODA, Toyota-shi (JP); Shinji Ichikawa, Nagoya-shi (JP); Taro Matsushita, Toyokawa-shi (JP); Tsubasa Migita, Osaka (JP); Shuta Ito, Toyota-shi (JP); Akio Uotani, Nagoya-shi (JP)

(73) Assignee: TOYOTA JIDOSHA KABUSHIKI KAISHA, Toyota-shi (JP)

(21) Appl. No.: 18/984,011

(22) Filed: Dec. 17, 2024

(30) Foreign Application Priority Data
Mar. 18, 2024 (JP) 2024-042212

(51) Int. Cl. G01R 31/66; G01R 31/00

(52) U.S. Cl. CPC G01R 31/66; G01R 31/006

(57) ABSTRACT

An abnormality detection system includes a vehicle and an abnormality detection device. The vehicle body 0 includes a current sensor (first sensor). Each of the plurality of battery packs (power storage modules) includes a current sensor (second sensor). The abnormality detection device performs abnormality determination based on a difference between the sum of the detection values of the current sensors of the plurality of battery packs and the detection value of the current sensor, and performs abnormality determination based on a deviation between the detection values of the current sensors of the plurality of battery packs.

### CROSS-REFERENCE TO RELATED APPLICATION

This application claims priority to Japanese Patent Application No. 2024-042212 filed on Mar. 18, 2024, incorporated herein by reference in its entirety.

### BACKGROUND

### 1. Technical Field

The present disclosure relates to an abnormality detection system.

### 2. Description of Related Art

Japanese Unexamined Patent Application Publication No. 2022-114896 (JP 2022-114896 A) discloses a vehicle including a plurality of replaceable battery modules.

### SUMMARY

In the vehicle described in JP 2022-114896 A, the resistance value of the battery module in relation to a load may increase due to a connection failure between the battery module and a vehicle body. In this case, a detection value of a sensor (current sensor etc.) provided in the vehicle changes due to the increase in the resistance value. In this case, it is difficult to determine whether the change in the detection value is caused by the connection failure or an abnormality in the sensor itself.

The present disclosure has been made to solve the above problem, and an object thereof is to provide an abnormality detection system capable of easily detecting a failure in connection of a power storage module to a vehicle.

An abnormality detection system according to a first aspect of the present disclosure includes a vehicle including a vehicle body and a plurality of power storage modules replaceably attached to the vehicle body and electrically connected in parallel to each other. The abnormality detection system includes an abnormality detection device configured to detect an electrical abnormality in the vehicle. The vehicle body includes a first sensor configured to detect a current value input to and output from each of the power storage modules, and each of the power storage modules includes a second sensor configured to detect a current value input to and output from the vehicle body. The abnormality detection device is configured to perform first abnormality determination based on a difference between a sum of detection values of the second sensors of the power storage modules and a detection value of the first sensor. The abnormality detection device is configured to perform second abnormality determination based on a deviation between the detection values of the second sensors of the power storage modules.

An abnormality detection system according to a second aspect of the present disclosure includes a vehicle including a vehicle body and a plurality of power storage modules replaceably attached to the vehicle body and electrically connected in series. The abnormality detection system includes an abnormality detection device configured to detect an electrical abnormality in the vehicle. The vehicle body includes a first circuit and a first sensor configured to detect a voltage value of the first circuit, and each of the power storage modules includes a second sensor configured to detect a voltage value. The power storage modules are electrically connected in parallel to the first circuit. Each of the power storage modules includes a second circuit and a second sensor configured to detect a voltage value of the second circuit. The abnormality detection device is configured to perform first abnormality determination based on a difference between a sum of detection values of the second sensors of the power storage modules and a detection value of the first sensor. The abnormality detection device is configured to perform second abnormality determination based on a deviation between the detection values of the second sensors of the power storage modules.

In the abnormality detection systems according to the first and second aspects of the present disclosure, the first abnormality determination and the second abnormality determination are performed as described above. Accordingly, it is possible to easily distinguish among a state in which an abnormality has occurred in the first sensor, a state in which an abnormality has occurred in the second sensor, a state in which a connection failure has occurred in the power storage module, and a normal state in which no abnormality has occurred. As a result, it is possible to easily detect the failure in connection of the power storage module to the vehicle.

The abnormality detection device may be configured to:
determine that an abnormality has occurred in either of the first sensor and the second sensor when the difference is larger than a first threshold in the first abnormality determination; and determine that a connection failure has occurred between any of the power storage modules and the vehicle body when detection is made that the difference is equal to or smaller than the first threshold in the first abnormality determination and then the deviation is larger than a second threshold in the second abnormality determination. With such a configuration, it is possible to easily determine whether an abnormality has occurred in either of the first sensor and the second sensor through the first abnormality determination. Further, it is possible to easily determine whether a connection failure has occurred in the power storage module by performing the second abnormality determination after determination is made that neither of the first sensor and the second sensor has an abnormality through the first abnormality determination.

The abnormality detection device may be configured to, after detection is made that the difference is larger than the first threshold in the first abnormality determination:
determine that an abnormality has occurred in the second sensor of any of the power storage modules when the deviation is larger than a third threshold in the second abnormality determination; and
determine that an abnormality has occurred in the first sensor when the deviation is equal to or smaller than the second threshold.

With such a configuration, it is possible to easily determine which of the first sensor and the second sensor has an abnormality by performing the second abnormality determination after determination is made that either of the first sensor and the second sensor has an abnormality through the first abnormality determination.

The abnormality detection device may be configured to perform a notification process for prompting a user of the vehicle to replace the power storage modules when determination is made that an abnormality has occurred in the second sensor through the first abnormality determination and the second abnormality determination. With such a configuration, the user can recognize that the power storage modules need to be replaced.

According to the present disclosure, it is possible to easily detect the failure in connection of the power storage module to the vehicle (vehicle body).

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a configuration of a battery replacement system according to a first embodiment;

FIG. 2 is a diagram illustrating a configuration of a vehicle according to the first embodiment;

FIG. 3 is a first view showing a sequence of a battery replacement system according to the first embodiment;

FIG. 4 is a second diagram showing a sequence of a battery replacement system according to the first embodiment;

FIG. 5 is a diagram illustrating a configuration of a battery replacement system according to a second embodiment;

FIG. 6 is a first view showing the sequencing of a battery replacement system according to a second embodiment; and

FIG. 7 is a second diagram illustrating a sequence of a battery replacement system according to a second embodiment.

### DETAILED DESCRIPTION OF EMBODIMENTS

Hereinafter, an embodiment of the present disclosure will be described in detail with reference to the drawings. The same or corresponding parts in the drawings are designated by the same reference signs and repetitive description will be omitted.

### First Embodiment

### System Configuration

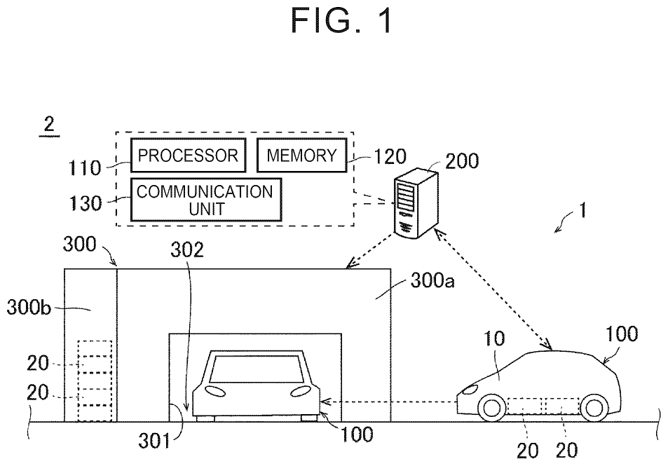

FIG. 1 is a diagram illustrating an abnormality detection system 1 and a battery replacement system 2 according to a first embodiment. The abnormality detection system 1 includes a vehicle 100 and an abnormality detection device 200. In the battery replacement system 2, a battery replacement device 300 is added to the abnormality detection system 1.

The vehicle 100 includes a vehicle body 10 and a plurality (two in the first embodiment) of battery packs 20. The two battery packs 20 are replaceably attached to the vehicle body 10. In the vehicle 100, the battery pack 20 is replaced in the battery replacement device 300. Accordingly, the battery pack 20 provided in the battery replacement device 300 is attached to the vehicle 100. The vehicle body 10 is a portion of the vehicle 100 other than the battery pack 20.

The battery pack 20 stores electric power used for driving (for example, traveling) the vehicle 100. The two battery packs 20 are arranged side by side in the front-rear direction of the vehicle 100, for example. The battery pack 20 is an example of a “power storage module” of the present disclosure.

The vehicles 100 are, for example, plug-in hybrid electric vehicle (PHEV), battery electric vehicle (BEV), or fuel cell electric vehicle (FCEV).

The abnormality detection device 200 is a device that detects an electrical abnormality in the vehicle 100. The abnormality detection device includes a processor 110, a memory 120, and a communication unit 130. The processor 110 controls the communication unit 130. The memory 120 stores a program to be executed by the processor 110 and information (for example, a map, a mathematical expression, and various parameters) used in the program. Note that the abnormality detection device 200 may be provided in the battery replacement device 300. Details of the processing of the abnormality detection device 200 will be described later.

The battery replacement device 300 includes a battery replacement device main body 300a in which battery replacement is performed, and a storage 300b in which the battery pack 20 is stored. The battery replacement device main body 300a is an apparatus that performs battery replacement for replacing the battery pack 20 mounted in the vehicle 100 with the battery pack 20 provided in the storage 300b. The storage 300b is installed in the battery replacement device main body 300a. The battery replacement device 300 (the battery replacement device main body 300a) is provided with an entrance 301 through which the vehicles 100 enter and exit.

The battery replacement device 300 is provided with a vehicle stop region 302. The battery replacement device 300 performs battery replacement in a state in which the vehicle 100 is stopped in the vehicle stop region 302. For example, in response to an operation of instructing (requesting) the start of the battery replacement operation in the car navigation device (not shown) of the vehicle 100 being performed by the user, an instruction signal for starting the battery replacement operation is transmitted from the vehicle 100 to the battery replacement device 300. The battery replacement device 300 starts control of the battery replacement operation in response to the reception of the instruction signal.

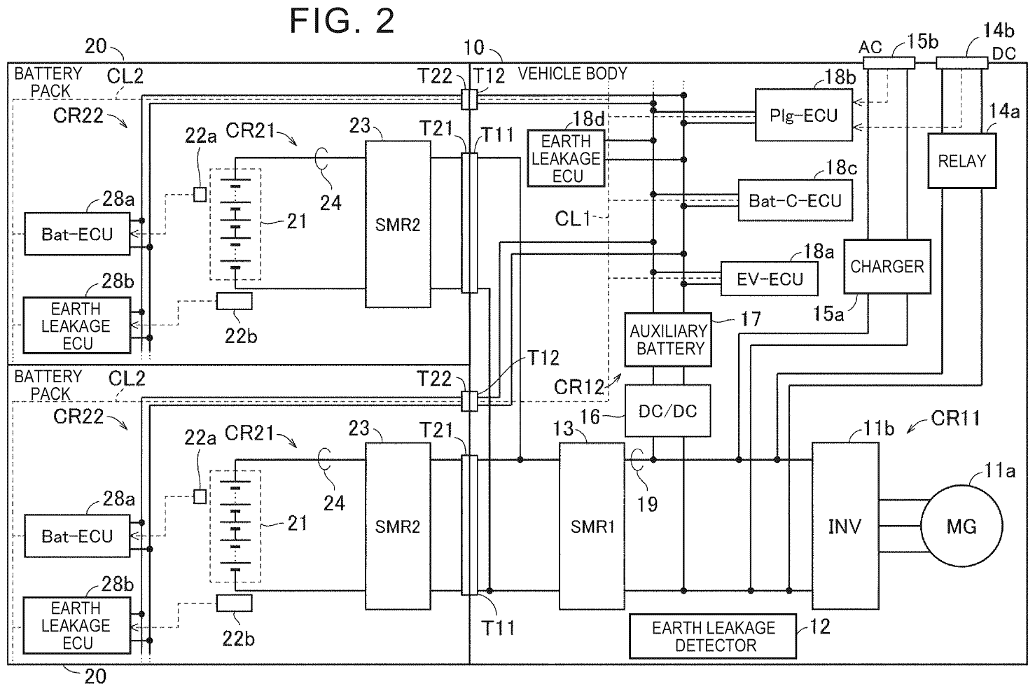

FIG. 2 is a diagram illustrating a configuration of a vehicle 100 according to the first embodiment. The vehicle body 10 includes a circuit CR11 and a circuit CR12. The battery pack 20 includes a circuit CR21 and a circuit CR22. The circuit CR21 corresponds to a first high-voltage circuit configured to apply a voltage (high voltage) generated by the battery cell 21 to the circuit CR11. The circuit CR11 corresponds to a second high-voltage circuit to which a voltage (high voltage) is applied from the battery cell 21. The circuit CR12 corresponds to a first low-voltage circuit configured to apply a voltage (low voltage) generated by the auxiliary battery 17 to the circuit CR22. The circuit CR22 corresponds to a second low-voltage circuit that receives a voltage (low voltage) from the auxiliary battery 17. A DC/DC converter 16 is provided between the circuit CR11 and the circuit CR12.

The two battery packs 20 (circuit CR21) are electrically connected in parallel to each other. Each of the two battery packs 20 (circuit CR21) is electrically connected in series with the vehicle body 10 (circuit CR11).

The circuit CR11 in the vehicle body 10 includes a motor generator (MG) 11a, an inverter 11b, a leakage detector 12, a DC charge relay 14a, a DC inlet 14b, a AC charger 15a, and a AC inlet 15b.

The circuit CR21 in the battery pack 20 is provided with a battery management system (BMS) 22a and a leakage detector 22b.

The vehicle body 10 further includes two terminals T11 to which the battery pack 20 is detachable, and a system main relay (SMR) 13 disposed between the terminals T11 and the circuit CR11. The circuit CR11 (high-voltage power supply line) is connected to the respective terminals T11 via a SMR13.

The battery pack 20 further includes a terminal T21 to which the vehicle body 10 is detachable, and a SMR23 disposed between the terminal T21 and the circuit CR21. The circuit CR21 (high-voltage power supply line) is connected to the terminal T21 via a SMR23.

The battery cell 21 is constituted by a secondary battery such as a lithium ion battery, a nickel metal hydride battery, or a sodium ion battery. The type of the secondary battery may be a liquid secondary battery or an all-solid secondary battery. A plurality of secondary batteries may form a battery pack.

The vehicle body 10 further includes two terminal T12. Circuit CR12 (low-voltage power supply lines) in the vehicle body 10 are connected to the respective terminals T12. The communication-line CL1 in the vehicle body 10 is also connected to the respective terminals T12. The battery pack 20 further includes a terminal T22. The circuit CR22 (low-voltage power supply line) in the battery pack 20 is connected to the terminal T22. The communication-line CL2 in the battery pack 20 is also connected to the terminal T22.

The auxiliary battery 17 outputs DC power to the circuit CR12 (low-voltage power supply line). The circuit CR12 further includes electronic control unit (ECU) 18a, 18b, 18c, and 18d in addition to the auxiliary battery 17. The circuit CR22 further comprises ECUs 28a and 28b. The auxiliary battery 17 supplies electric power to each of ECU 18a˜18d and 28a, 28b connected to the low-voltage power supply line, for example.

ECU 18a corresponds to a control device (EV-ECU) that controls various types of control related to the vehicles 100. ECU 18a receives information of each of the plurality of battery packs 20 through communication through the communication-line CL1. Specifically, ECU 18a receives data from each of ECU 28a and ECU 28b.

ECU 18b corresponds to a control device (Plg-ECU) that detects the status of each of DC inlet 14b and AC inlet 15b. ECU 18c corresponds to a control device (Bat-C-ECU) that controls DC charge-relay 14a and AC charger 15a. ECU 18d corresponds to a control device that monitors an electric leakage condition of the circuit CR11.

ECU 28a corresponds to a control device (Bat-ECU) that monitors the status of the battery cells 21 and controls SMR23. ECU 28b corresponds to a control device that monitors an electric leakage condition of the circuit CR21. ECU are communicably connected to each other via an in-vehicle network (e.g., a controller area network (CAN)).

The leakage detector 12 detects a leakage state related to the circuit CR11, and outputs the detected leakage state to ECU 18d. BMS22a detects the condition (current, voltage, temperature, etc.) of the battery cell 21, and outputs the detected condition to ECU 28a. The leakage detector 22b detects a leakage state related to the circuit CR21, and outputs the detected leakage state to ECU 28b.

Each of SMR13 and SMR23 switches the connection/disconnection of the electrical path between the circuit CR11 and the circuit CR21. ECU 18a brings both SMR13 and SMR23 into a closed state (connected state) when the voltage of the battery cell 21 is applied to the circuit CR11. When the voltage of the battery cell 21 is not applied to the circuit CR11, ECU 18a sets at least one of SMR13 and SMR23 to the open state (cut-off state). When the vehicles 100 are driven (traveling, charging, etc.), SMR13 and the two SMR23 are closed.

The terminal T21 and the terminal T22 of the battery pack 20 are attachable to and detachable from the terminal T11 and the terminal T12 of the vehicle body 10, respectively. When the terminals T21 and T22 are connected to the terminals T11 and T12, respectively, the battery pack 20 is attached to the vehicle body 10.

The vehicle body 10 includes a current sensor 19. The current sensor 19 detects a current value input and output to and from the plurality of battery packs 20. The current sensor 19 is provided between a connecting point between the circuit CR11 and the circuit CR12 and SMR13. Note that the current sensor 19 is an example of the “first sensor” of the present disclosure.

Each battery pack 20 includes a current sensor 24. The current sensor 24 is provided between SMR23 and the battery cell 21. Each current sensor 24 detects a current value input and output to and from the vehicle body 10. The current sensor 24 is an example of a “second sensor” of the present disclosure.

Here, in the conventional vehicle, it is considered that the resistance value increases due to a connection failure between the battery pack and the vehicle body. In this case, although the detection value of the current sensor provided in the vehicle body or the battery pack changes due to the increase in the resistance value, it is difficult to determine whether the change of the detection value is due to the above-described connection failure or an abnormality of the current sensor itself.

Therefore, in the first embodiment, the abnormality detection device 200 performs the first abnormality determination and the second abnormality determination. The first abnormality determination is a determination based on a difference between a sum of detection values of the current sensors 24 of the plurality of battery packs 20 and a detection value of the current sensor 19 of the vehicle body 10. The second abnormality is judged. The determination is based on a deviation between detection values of the current sensors 24 of the plurality of battery packs 20. By performing the first abnormality determination and the second abnormality determination, it is possible to determine an abnormality of the current sensor 19, an abnormality of the current sensor 24, a connection failure between the vehicle body 10 and the battery pack 20, and a normal state.

### Sequence of Systems

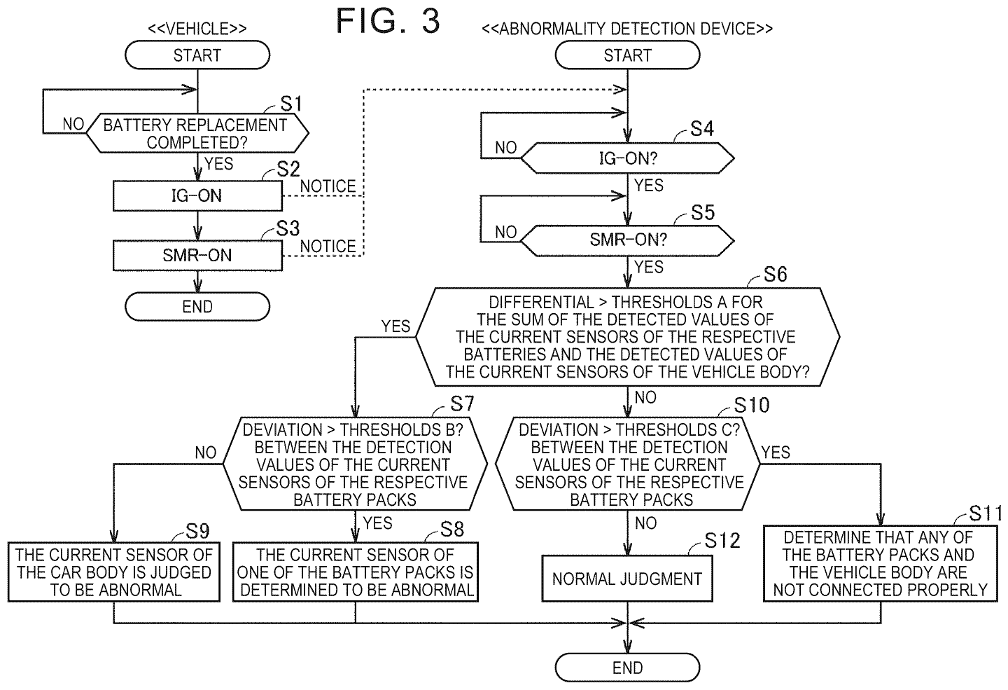

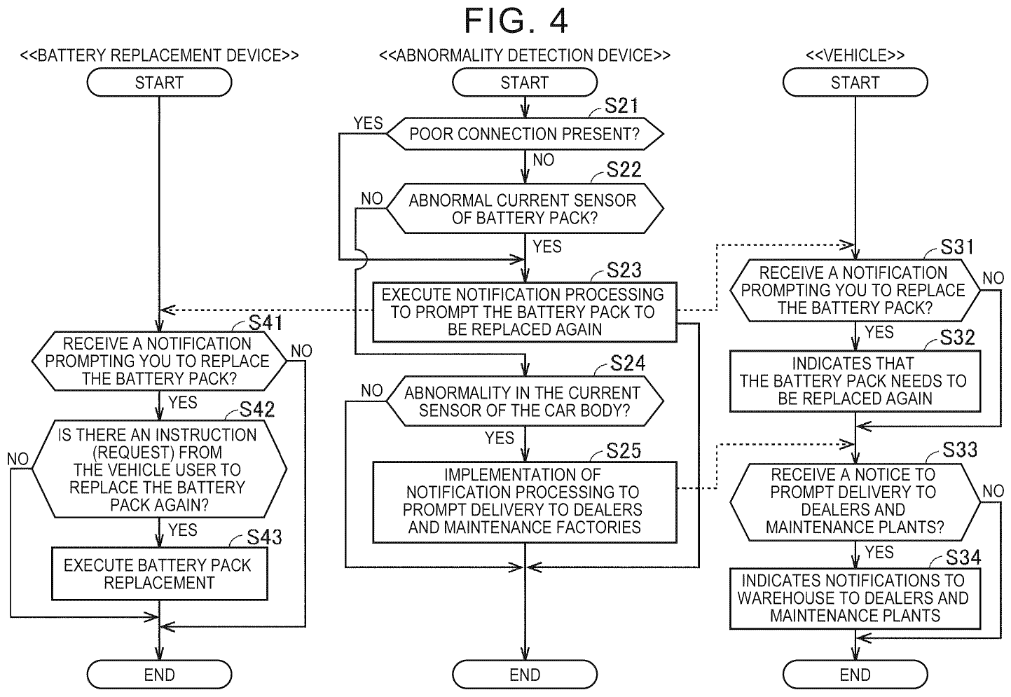

FIG. 3 and FIG. 4 show sequence control of the abnormality detection system 1 and the battery replacement system 2, respectively. The processing by the abnormality detection device 200 is executed by the processor 110 (FIG. 1). In addition, the sequence of FIGS. 3 and 4 is performed in the battery replacement device 300 before the vehicle 100 starts traveling.

Referring to FIG. 3, in S1, the vehicle 100 determines whether the replacement of the battery pack 20 has been completed. The vehicle 100 may determine that the replacement of the battery pack 20 has been completed, for example, based on information from the battery replacement device 300, or may determine, for example, based on a connection state between the battery pack 20 and the vehicle body 10.

In S2, the vehicle 100 turns on the ignition power supply and transmits information indicating that the ignition power supply has been turned on to the abnormality detection device 200. In S3, the vehicles 100 turn on each of SMR13 and 23 (FIG. 2) and transmit information to the abnormality detection device 200 indicating that each of SMR13 and SMR23 has been turned on. Thus, the circuit CR11 and the circuit CR21 (FIG. 2) are electrically connected to each other.

In S4, the abnormality detection device 200 determines whether or not the ignition power supply is turned on. If it is determined that the ignition power supply is turned on (Yes in S4), the process proceeds to S5. When it is determined that the ignition power supply is not turned on (No in S4), S4 process is repeated.

In S5, the abnormality detection device 200 determines whether each of SMR13 and 23 is turned on. If it is determined that each of SMR13 and 23 is turned on (Yes in S5), the process proceeds to S6. When it is determined that each of SMR13 and 23 is not turned on (No in S5), S5 process is repeated.

In S6, the abnormality detection device 200 determines whether or not the difference between the sum of the detection values of the current sensors 24 of the respective battery packs 20 and the detection values of the current sensors 19 of the vehicle body 10 is larger than the threshold A. The difference means an absolute value of a difference between the sum and a detection value of the current sensor 19. If the difference is greater than the threshold A (Yes in S6), the process proceeds to S7. When the difference is equal to or smaller than the threshold A (No in S6), the process proceeds to S10. Note that the threshold A is an example of the “first threshold” of the present disclosure. Further, S6 determination process is an exemplary “first anomaly determination” of the present disclosure.

Note that, after each of SMR13 and 23 is turned on, the abnormality detection device 200 may cause a test current for performing determination after S6 to flow to the vehicles 100.

In S7, the abnormality detection device 200 determines whether or not the deviation of the detection values of the current sensors 24 of the respective battery packs 20 is larger than the threshold B. The deviation means an absolute value of a difference between detection values of the two current sensors 24. If the deviation is greater than the threshold B (Yes in S7), the process proceeds to S8. If the difference is less than or equal to the threshold B (No in S7), the process proceeds to S9. The threshold B is an example of the “third threshold” of the present disclosure. S7 determination process is an exemplary “second anomaly determination” of the present disclosure.

In S8, the abnormality detection device 200 determines that the current sensor 24 of one of the two battery packs 20 is abnormal. Thereafter, the process ends.

In S9, the abnormality detection device 200 determines that the current sensor 19 of the vehicle body 10 is abnormal. Thereafter, the process ends.

In S10, the abnormality detection device 200 determines whether or not the deviation of the detection values of the current sensors 24 of the respective battery packs 20 is larger than the threshold C. The deviation means an absolute value of a difference between detection values of the two current sensors 24. If the deviation is greater than the threshold C (Yes in S10), the process proceeds to S11. If the difference is less than or equal to the threshold C (No in S10), the process proceeds to S12. Note that the threshold C is an example of the “second threshold” of the present disclosure. S10 determination process is an exemplary “second anomaly determination” of the present disclosure. The threshold C may be smaller than the threshold B.

In S11, the abnormality detection device 200 determines that there is a connection failure between any one of the two battery packs 20 and the vehicle body 10. Thereafter, the process ends.

In S12, the abnormality detection device 200 determines that the condition is normal. Specifically, the abnormality detection device 200 determines that there is no abnormality of the current sensor 19, abnormality of the current sensor 24, and connection failure. Thereafter, the process ends.

FIG. 4 is a sequence diagram illustrating control after an abnormality (or normal) is determined in the sequence control of FIG. 3.

In S21, the abnormality detection device 200 determines whether or not there is a connection failure between the battery pack 20 and the vehicle body 10. That is, the abnormality detection device 200 determines whether or not the process of S11 (FIG. 3) has been executed. If it is determined that there is a connection failure (Yes in S21), the process proceeds to S23. If it is determined that there is no connection failure (No in S21), the process proceeds to S22.

In S22, the abnormality detection device 200 determines whether or not there is an abnormality in the current sensor 24 of one of the two battery packs 20. That is, the abnormality detection device 200 determines whether or not the process of S8 (FIG. 3) has been executed. If it is determined that there is an abnormality in the current sensor 24 (Yes in S22), the process proceeds to step 23. When it is determined that there is no abnormality in the current sensor 24 (No in S22), the process proceeds to S24.

In S23, the abnormality detection device 200 performs a notification process for prompting each of the vehicles 100 and the battery replacement device 300 to re-replace the battery pack 20 through the communication unit 130 (FIG. 1). Specifically, the abnormality detection device 200 transmits information indicating that the battery pack 20 needs to be replaced again to each of the vehicle 100 and the battery replacement device 300 through the communication unit 130 (FIG. 1). Thereafter, the process ends. Note that the notification may be performed only on one of the battery replacement device 300 and the vehicle 100.

Further, after S21 determines that there is a connection failure and the battery pack 20 is replaced again, it may be determined that there is a connection failure in S21. In this case, the abnormality detection device 200 may determine that there is an abnormality in the vehicle 100 (terminal T11 or the like) and execute a notification process for prompting the user to enter the dealer or the maintenance shop.

In S24, the abnormality detection device 200 determines whether there is an abnormality in the current sensor 19 of the vehicle body 10. That is, the abnormality detection device 200 determines whether or not the process of S9 (FIG. 3) has been executed. When it is determined that there is an abnormality in the current sensor 19 (Yes in S24), the process proceeds to S25. When it is determined that there is no abnormality in the current sensor 19 (No in S24), the process ends.

In S25, the abnormality detection device 200 executes a notification process for prompting the user to enter the dealer or the maintenance shop. Specifically, the abnormality detection device 200 transmits information indicating that storage in the above-described facility is necessary to the vehicle 100 through the communication unit 130 (FIG. 1). Thereafter, the process ends.

Note that the order in which S21, S22 and S24 determination processes are performed is not limited to that illustrated in FIG. 4.

In S31, the vehicle 100 determines whether or not a notification (notification by S23 notification process) prompting re-replacement of the battery pack 20 has been received. If a notification prompting re-exchange is received (Yes in S31), the process proceeds to S32. If a notification is not received (No in S31), the process proceeds to S33.

In S32, the vehicle 100 causes a display terminal, such as a car navigation device, to display a notification prompting re-replacement of the battery pack 20.

In S33, the vehicles 100 determine whether or not a notification (notification by the notification process in S25) prompting the dealer or the maintenance shop to enter has been received.

In S34, the vehicle 100 causes a display terminal, such as a car navigation device, to display a notification prompting warehousing.

In S41, the battery replacement device 300 determines whether or not a notification (notification by S23 notification process) prompting the replacement of the battery pack 20 has been received. If a notification prompting re-exchange is received (Yes in S41), the process proceeds to S42. If a notification prompting re-replacement has not been received (No in S41), the process ends.

In S42, the battery replacement device 300 determines whether or not there is an instruction (requested) from the user of the vehicle 100 to re-replace the battery pack 20. If there is an instruction (Yes in S42), the process proceeds to S43. If there is no instruction (No in S42), the process ends.

In S43, the battery replacement device 300 performs a re-replacement of the battery pack 20. After the re-replacement of the battery pack 20 is completed, the process returns to S1 (FIG. 3).

As described above, in the first embodiment, the abnormality detection device 200 performs two abnormality determinations. One is abnormality determination based on a difference between the sum of the detection values of the current sensors 19 of the plurality of battery packs 20 and the detection values of the current sensors 19 of the vehicle body 10. The other is an abnormality determination based on a deviation between detection values of the current sensors 19 of the plurality of battery packs 20. This makes it possible to easily distinguish between a connection failure between the battery pack 20 and the vehicle body 10 and an abnormality of the current sensor 19 or the current sensor 24. As a result, it is possible to appropriately notify the user of the vehicle 100 after the abnormality determination.

In the first embodiment, the abnormality detection device 200 performs abnormality determination based on the difference before the abnormality determination based on the deviation. This makes it possible to check the reliability of the current sensors 19 and 24 and then determine whether there is a connection failure. Second embodiment

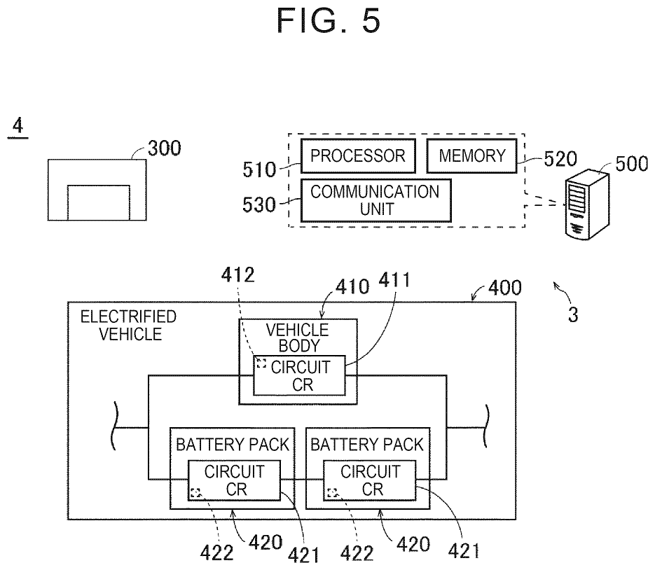

A second embodiment of the present disclosure will be described with reference to FIGS. 5 to 7. In the second embodiment, the battery packs 420 are electrically connected in series. The same components as those in the first embodiment are denoted by the same reference numerals and will not be described repeatedly. Configurations having the same names as those of the first embodiment are the same as those of the first embodiment, and thus description thereof may be omitted or simplified.

### System Configuration

FIG. 5 is a diagram illustrating the abnormality detection system 3 and the battery replacement system 4 according to the second embodiment. The abnormality detection system 3 includes a vehicle 400 and an abnormality detection device 500. In the battery replacement system 4, a battery replacement device 300 is added to the abnormality detection system 3.

The vehicle 400 includes a vehicle body 410 and a plurality (two in the second embodiment) of battery packs 420. The abnormality detection device 500 includes a processor 510, a memory 520, and a communication unit 530. The battery pack 420 is an example of a “power storage module” of the present disclosure.

The vehicle body 410 includes a circuit CR411. The circuit CR411 is a circuit corresponding to the circuit CR11 of the first embodiment. The vehicle body 410 (circuit CR411) includes a voltage sensor 412. The voltage sensor 412 acquires the voltage of the circuit CR11. Note that the circuit CR411 and the voltage sensor 412 are exemplary “first circuit” and “first sensor” of the present disclosure, respectively.

The battery pack 420 includes a circuit CR421. The circuit CR421 is a circuit corresponding to the circuit CR21 of the first embodiment. The battery pack 420 (circuit CR421) includes a voltage sensor 422. In the battery pack 420, the voltage sensor 422 acquires the voltage of the circuit CR421. The circuit CR421 and the voltage sensor 422 are exemplary of the “second circuit” and the “second sensor”, respectively.

The two battery packs 420 (circuit CR421) are electrically connected in series. The two battery packs 420 (circuit CR421) are electrically connected in parallel to the vehicle body 410 (circuit CR411).

### Sequence of Systems

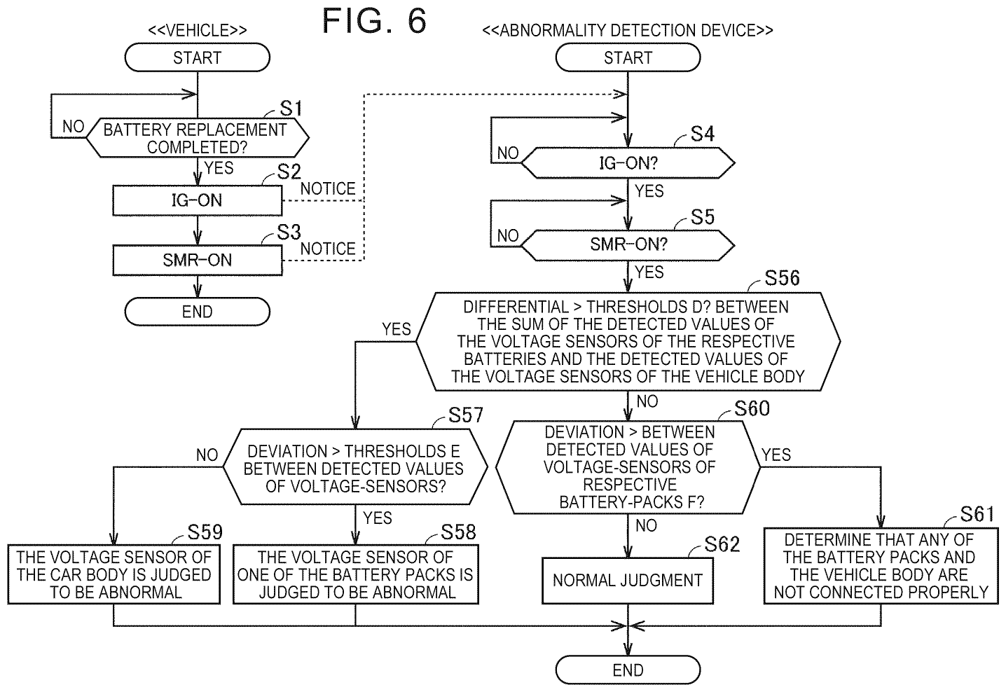

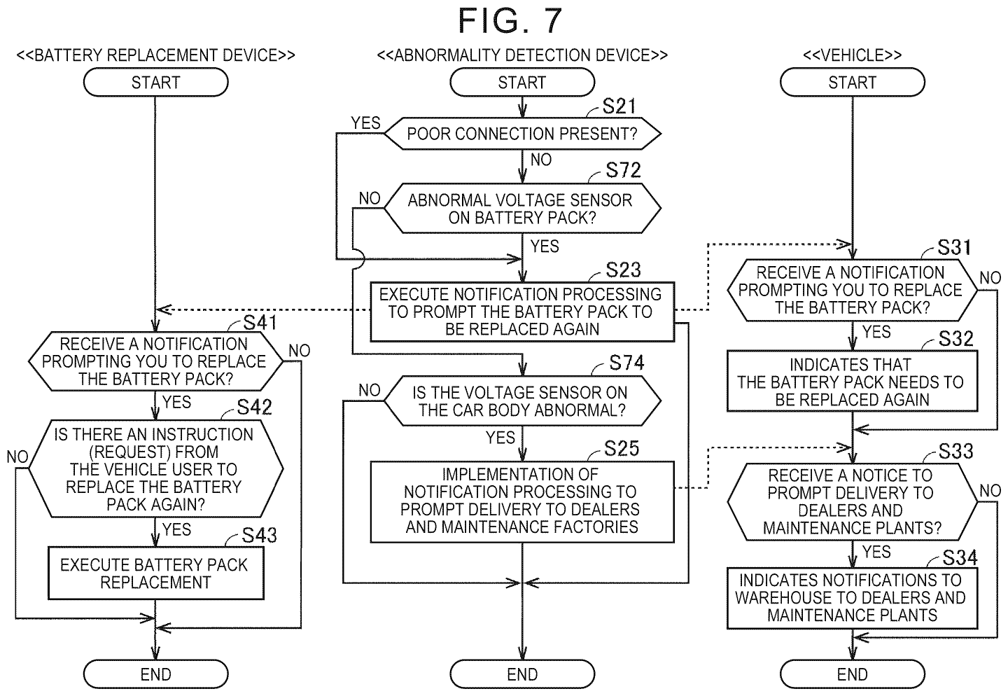

Next, the sequence control of the battery replacement system 4 (abnormality detection system 3) will be described with reference to FIGS. 6 and 7.

In S56 after S5, the abnormality detection device 500 determines whether or not the difference between the sum of the detection values of the voltage sensors 422 of the respective battery packs 420 and the detection values of the voltage sensors 412 of the vehicle body 410 is larger than the threshold D. The difference means an absolute value of a difference between the sum and the voltage sensor 412. If the difference is greater than the threshold D (Yes in S56), the process proceeds to S57. If the difference is less than or equal to the threshold D (No in S56), the process proceeds to S60. Note that the threshold D is an example of the “first threshold” of the present disclosure. Further, S56 determination process is an exemplary “first anomaly determination” of the present disclosure.

Note that, after each of SMR13 and 23 is turned on, the abnormality detection device 500 may cause a test current for performing determination after S56 to flow to the vehicles 400.

In S57, the abnormality detection device 500 determines whether or not the difference between the detection values of the voltage sensors 422 of the respective battery packs 420 is larger than the threshold E. The deviation means an absolute value of a difference between detection values of the two voltage sensors 422. If the deviation is greater than the threshold E (Yes in S57), the process proceeds to S58. If the difference is less than or equal to the threshold E (No in S57), the process proceeds to S59. Note that the threshold E is an example of the “third threshold” of the present disclosure. S57 determination process is an exemplary “second anomaly determination” of the present disclosure.

In S58, the abnormality detection device 500 determines that the voltage sensor 422 of one of the two battery packs 420 is abnormal. Thereafter, the process ends.

In S59, the abnormality detection device 500 determines that the voltage sensor 412 of the vehicle body 410 is abnormal. Thereafter, the process ends.

In S60, the abnormality detection device 500 determines whether or not the difference between the detection values of the voltage sensors 422 of the respective battery packs 420 is larger than the threshold F. The deviation means an absolute value of a difference between detection values of the two voltage sensors 422. If the deviation is greater than the threshold F (Yes in S60), the process proceeds to S61. If the difference is less than or equal to the threshold F (No in S60), the process proceeds to S62. Note that the threshold F is an example of the “second threshold” of the present disclosure. S60 determination process is an exemplary “second anomaly determination” of the present disclosure. The threshold F may be smaller than the threshold E.

In S61, the abnormality detection device 500 determines that there is a connection failure between any one of the two battery packs 420 and the vehicle body 410. Thereafter, the process ends.

In S62, the abnormality detection device 500 determines that an electric abnormality in the vehicle 400 is not detected and is in a normal condition. Thereafter, the process ends.

FIG. 7 is a sequence diagram showing the same control as in FIG. 4 of the first embodiment. In the second embodiment, S72 is executed instead of S22 (FIGS. 4), and S74 is executed instead of S24 (FIG. 4).

In S72, the abnormality detection device 500 determines whether there is an abnormality in the voltage sensor 422 of the battery pack 420. If there is an error in the voltage sensor 422 (Yes in S72), the process proceeds to S23. If there is no abnormality in the voltage sensor 422 (No in S72), the process proceeds to S74.

In S74, the abnormality detection device 500 determines whether or not there is an abnormality in the voltage sensor 412 of the vehicle body 410. If there is an error in the voltage sensor 412 (Yes in S74), the process proceeds to S25. When there is no abnormality in the voltage sensor 412 (No in S74), the process ends.

In the first and second embodiments described above, the following examples are shown, but the present disclosure is not limited thereto. That is, the abnormality determination is performed based on the difference between the sum of the detection values of the sensors (24, 422) of the battery pack and the detection values of the sensors (19, 412) of the vehicle body, and thereafter, the abnormality determination is performed based on the deviation between the detection values of the respective battery packs. The order of the abnormality determination may be reversed.

In the first and second embodiments, the abnormality determination is performed when electrified vehicle is disposed in the battery replacement device. For example, the abnormality determination may be performed while the vehicle is traveling. In this case, the abnormality detection device may be provided in the vehicle.

In the first and second embodiments described above, an example has been described in which a notification prompting re-replacement of the battery pack and a notification prompting entry to a dealer or the like are displayed on a car navigation device or the like of the vehicle, but the present disclosure is not limited thereto. For example, the notification may be displayed on a user's terminal (e.g., smart phone, PC, etc.). In addition, instead of the notification prompting the user to enter the dealer or the like, a notification process for prompting the user to refrain from traveling the vehicle may be executed.

In the first and second embodiments described above, an example has been described in which, when there is an abnormality in the current sensor of the battery pack and when there is a connection failure between the vehicle body and the battery pack, a notification prompting the replacement of the battery pack is given, but the present disclosure is not limited thereto. For example, only an abnormality and a connection failure may be notified.

In the first embodiment, SMR is provided in each of the battery pack 20 and the vehicle body 10, but the present disclosure is not limited thereto. SMR may be provided only in one of the battery pack 20 and the vehicle body 10. This modification may also be applied to the second embodiment.

Note that the configurations (processes) of the above-described embodiments and the above-described modification examples may be combined with each other.

The embodiment disclosed herein shall be construed as exemplary and not restrictive in all respects. The scope of the present disclosure is shown by the claims rather than by the above description of the embodiments, and is intended to include all modifications within the meaning and scope equivalent to those of the claims.

What is claimed is:

1. An abnormality detection system comprising:
a vehicle including a vehicle body and a plurality of power storage modules replaceably attached to the vehicle body and electrically connected in parallel to each other; and
an abnormality detection device configured to detect an electrical abnormality in the vehicle, wherein
the vehicle body includes a first sensor configured to detect a current value input to and output from each of the power storage modules,
each of the power storage modules includes a second sensor configured to detect a current value input to and output from the vehicle body, and
the abnormality detection device is configured to perform:
first abnormality determination based on a difference between a sum of detection values of the second sensors of the power storage modules and a detection value of the first sensor; and
second abnormality determination based on a deviation between the detection values of the second sensors of the power storage modules.

2. An abnormality detection system comprising:
a vehicle including a vehicle body and a plurality of power storage modules replaceably attached to the vehicle body and electrically connected in series; and
an abnormality detection device configured to detect an electrical abnormality in the vehicle, wherein
the vehicle body includes:
a first circuit; and
a first sensor configured to detect a voltage value of the first circuit,
the power storage modules are electrically connected in parallel to the first circuit,
each of the power storage modules includes:
a second circuit; and
a second sensor configured to detect a voltage value of the second circuit, and
the abnormality detection device is configured to perform:
first abnormality determination based on a difference between a sum of detection values of the second sensors of the power storage modules and a detection value of the first sensor; and
second abnormality determination based on a deviation between the detection values of the second sensors of the power storage modules.

3. The abnormality detection system according to claim 1, wherein the abnormality detection device is configured to:
determine that an abnormality has occurred in either of the first sensor and the second sensor when the difference is larger than a first threshold in the first abnormality determination; and
determine that a connection failure has occurred between any of the power storage modules and the vehicle body when detection is made that the difference is equal to or smaller than the first threshold in the first abnormality determination and then the deviation is larger than a second threshold in the second abnormality determination.

4. The abnormality detection system according to claim 2, wherein the abnormality detection device is configured to:
determine that an abnormality has occurred in either of the first sensor and the second sensor when the difference is larger than a first threshold in the first abnormality determination; and
determine that a connection failure has occurred between any of the power storage modules and the vehicle body when detection is made that the difference is equal to or smaller than the first threshold in the first abnormality determination and then the deviation is larger than a second threshold in the second abnormality determination.

5. The abnormality detection system according to claim 3, wherein the abnormality detection device is configured to, after detection is made that the difference is larger than the first threshold in the first abnormality determination:
determine that an abnormality has occurred in the second sensor of any of the power storage modules when the deviation is larger than a third threshold in the second abnormality determination; and
determine that an abnormality has occurred in the first sensor when the deviation is equal to or smaller than the second threshold.

6. The abnormality detection system according to claim 4, wherein the abnormality detection device is configured to, after detection is made that the difference is larger than the first threshold in the first abnormality determination:
determine that an abnormality has occurred in the second sensor of any of the power storage modules when the deviation is larger than a third threshold in the second abnormality determination; and
determine that an abnormality has occurred in the first sensor when the deviation is equal to or smaller than the second threshold.

7. The abnormality detection system according to claim 1, wherein the abnormality detection device is configured to perform a notification process for prompting a user of the vehicle to replace the power storage modules when determination is made that an abnormality has occurred in the second sensor through the first abnormality determination and the second abnormality determination.

8. The abnormality detection system according to claim 2, wherein the abnormality detection device is configured to perform a notification process for prompting a user of the vehicle to replace the power storage modules when determination is made that an abnormality has occurred in the second sensor through the first abnormality determination and the second abnormality determination.
